(19) United States
(12) Patent Application Publication
(10) Pub. No.: US 2020/0062995 A1
(43) Pub. Date: Feb. 27, 2020

(54) LOW GLOSS BLACK POLYIMIDE FILM COMPRISING A STRESS CANCELING RESIN LAYER AND A METHOD FOR PRODUCING THE SAME

(71) Applicant: KUK DO CHEMICAL CO., LTD., Seoul (KR)

(72) Inventors: Bum-Young MYUNG, Seongnam-si (KR); Seung-Kyun KIM, Seoul (KR); Joo-Bin KIM, Seoul (KR); Seung-Heon KIM, Siheung-si (KR); Sang-Wan KIM, Incheon (KR); Ji-Hoon LEE, Seoul (KR); Yu-Bin KIM, Nam-gu (KR)

(73) Assignee: KUK DO CHEMICAL CO., LTD., Seoul (KR)

(21) Appl. No.: 16/542,914

(22) Filed: Aug. 16, 2019

(30) Foreign Application Priority Data
Aug. 22, 2018 (KR) 10-2018-0097885

(51) Int. Cl. C09D 179/08; C09D 5/32

(52) U.S. Cl. CPC C09D 179/08; H05K 9/0081; C09D 5/32

(57) ABSTRACT

Disclosed is a low gloss black polyimide film produced from a soluble black polyimide resin composition capable of realizing matte by surface transfer of a support film, without addition of a matting agent. Also provided is a black polyimide film including a stress canceling resin layer and having no curl or distortion. The black polyimide film includes: a stress canceling resin layer; a support film; and a black polyimide resin layer coated on the support film in a flexible manner, wherein low gloss is realized without addition of a matting agent, and the stress canceling resin layer for residual stress cancellation of the black polyimide resin layer is provided on the other surface of the support film.

### CROSS REFERENCE

This application claims priority from Korean patent application no. 10-2018-0097885 filed Aug. 22, 2018 in the Korea Intellectual Property Office, of which contents are incorporated herein by reference in its entirety.

### TECHNICAL FIELD

The present invention provides a low gloss black polyimide film produced from a soluble black polyimide resin composition capable of realizing matte by surface transfer of a support film, without addition of a matting agent, and also provides a black polyimide film including a stress canceling resin layer so as to prevent curl, distortion, and the like. Accordingly, the present invention relates to a black polyimide film which further improves heat resistance, insulation, and optical/shielding properties which are useful for the application of the black polyimide as a coverlay or an electromagnetic wave shielding film (EMI) material for producing a flexible printed circuit board.

### BACKGROUND ART

Generally, polyimides are a generic term for polymers having an acid imide structure. Polyimides are produced by condensation with aromatic tetracarboxylic anhydrides and aromatic diamines. Polyimides have excellent properties such as high heat resistance, radiation resistance, and chemical resistance. Polyimides are widely used as high-tech materials and insulating coating agents in the field of electrical electronics, semiconductors, displays, automobiles, aerospace, and space materials. However, the use of polyimides has been limited due to “insoluble and non-melting” properties that polyimides do not dissolve in a solvent and are not thermoformed. Most polyimides are used by processing a polyamic acid, which is a precursor, performing high-temperature thermal treatment, and performing a curing imidization process. A representative product produced by such a method is a polyimide film.

Polyimide films are widely used as barrier films for protecting flexible circuit boards, electronic components, lead frames of integrated circuit packages, and the like. Particularly, in recent years, insulating layers become thinner as electronic components are lighter, thinner, shorter, and smaller, and security/shielding/visual effect are required. Therefore, the demand for low gloss black polyimide films is rapidly increasing. Therefore, the demand for low gloss black polyimide films is increasing in spite of high selling prices. In a conventional producing method, there is a limitation in realizing low gloss and thin film production is difficult. Therefore, there is an urgent need for developing an alternative method.

Korean Patent Registration No. 10-1813263 discloses a black polyimide film having low gloss through surface transfer of a support film having a low gloss surface property, without addition of a matting agent. However, there is a problem that the support film is greatly curled, distorted, or warped inward from a polyimide resin layer during a flexible coating process of a polyimide resin layer. Due to this, a subsequent adhesive coating process is impossible, or a coverlay matching process for circuit protection is difficult in the manufacture of a flexible printed wiring board. The present invention has been accomplished by finding out that this problem is caused by a residual stress difference due to a thermal history occurring between a polyimide resin layer and a support film during a flexible application process.

### CITATION LIST

[Patent Literature] (Korean Patent Literature) Patent Registration No. 10-1813263 (2018 Jan. 30.)

### SUMMARY OF INVENTION

### Technical Problem

The present invention has been made in an effort to solve the problems of the related art and the technical problems described above.

An object of the present invention is to implement a low gloss black insulating layer for producing an electromagnetic wave shielding (EMI) film or a coverlay film for a flexible printed wiring board without problems such as the curl, distortion, and warpage during the flexible coating of the black polyimide resin by including a stress canceling resin layer on one surface of a support film, including a black polyimide resin layer on the other surface thereof, and specifying the composition and physical properties thereof.

### Solution to Problem

In order to achieve the above-described objects of the present invention and achieve the characteristic effects of the present invention described below, the characteristic construction of the present invention is as follows.

One embodiment of the present invention provides a black polyimide film including: a stress canceling resin layer; a support film; and a black polyimide resin layer coated on the support film in a flexible manner, wherein (A) low gloss is realized by surface transfer of the black polyimide resin layer coated on one surface of the support film in a flexible manner, without addition of a matting agent, (B) the stress canceling resin layer for residual stress cancellation of the black polyimide resin layer is provided on the other surface of the support film, (C) peel strength between the support film and the black polyimide resin layer is 4 gf/cm to 40 gf/cm, (D) a 60-degree gloss value of an inner surface of the black polyimide film is 0 to 60, (E) modulus of elasticity is 1 GPa to 5 GPa, (F) tensile strength is 20 MPa to 100 Mpa, (G) elongation is 5% to 50%, (H) a glass transition temperature is 150° C. to 300° C., (I) a surface resistance is 10¹⁰ Ωcm or more, and (J) a thickness is 1 μm to 10 μm.

In the black polyimide film according to one embodiment of the present invention, the stress canceling resin layer may includes at least one selected from the group consisting of polyamide imide, polyimide, a polyvinyl chloride resin, polystyrene, an ABS resin, an acrylic resin, polyethylene, polypropylene, polyester, polyurethane, and cellulose acetate.

In the black polyimide film according to one embodiment of the present invention, the thickness of the stress canceling resin layer is 70% to 120% of the thickness of the black polyimide resin layer, and the curl level during the flexible coating of the black polyimide resin layer is 0% to 15%.

In the black polyimide film according to one embodiment of the present invention, the black polyimide resin layer includes a solvent-soluble polyimide resin composition and a carbon black, the solvent-soluble polyimide resin composition includes an isocyanate composition and an acid anhydride, and the acid anhydride includes 80 mol % to 100 mol % of trimellitic anhydride and 0 mol % to 20 mol % of pyromellitic anhydride.

In the black polyimide film according to one embodiment of the present invention, the carbon black includes 3 wt % to 10 wt % of carbon black with respect to the polyimide resin solid.

In the black polyimide film according to one embodiment of the present invention, the isocyanate includes at least one of diphenylmethane diisocyanate and toluene.

One embodiment of the present invention provides a method for producing a black polyimide film, including: a step (a) of coating a stress canceling resin layer on a back surface of a support film having a matt surface in a flexible manner; a step (b) of reacting at least one isocyanate compound selected from diphenylmethane diisocyanate and toluene diisocyanate with trimellitic anhydride in the presence of a solvent at 30° C. to 100° C. for 1 hour to 2 hours; a step (c) of adding pyromellitic anhydride after the step (b) and reacting at 120° C. to 140° C. for 1 hour to 4 hours; a step (d) of preparing a soluble polyimide solution by discharging carbon dioxide, which is a by-product generated after the step (c); a step (e) of adding a dispersant after the step (d) and performing a milling process; a step (f) of preparing a polyimide resin composition by adding 3 wt % to 10 wt % of a carbon black with respect to a polyimide resin solid after the step (e); and a step (g) of coating the polyimide resin layer on the support film to a thickness of 1 μm to 10 μm in a flexible manner.

One embodiment of the present invention provides a low gloss electromagnetic wave shielding film (EMI) or a coverlay film for a flexible printed wiring board using the black polyimide film.

### Advantageous Effects of Disclosure

The present invention has an effect that provides a low gloss black polyimide film produced from a soluble black polyimide resin composition capable of realizing matte by surface transfer of a support film, without addition of a matting agent.

According to the present invention, since the implementation of low gloss is facilitated by release transfer of a support film, a thin film can be easily produced. Further, due to high-strength soft mechanical properties, excellent heat resistance, insulation, and optical/shielding properties are provided. Therefore, it is suitable for application of insulation materials for a coverlay or an electromagnetic wave shielding film (EMI) for producing a flexible printed circuit board. Particularly, due to the stress canceling resin layer of the support film, excellent flatness is provided without problems such as the curl, distortion, and warpage during the flexible coating process of the soluble polyimide resin. Therefore, it is possible to solve the problems that a subsequent adhesive coating process is impossible, or a coverlay matching process for circuit protection is difficult in the manufacture of a flexible printed wiring board.

### BRIEF DESCRIPTION OF DRAWINGS

FIG. 1 is a cross-sectional view illustrating a layer structure of a black polyimide film.

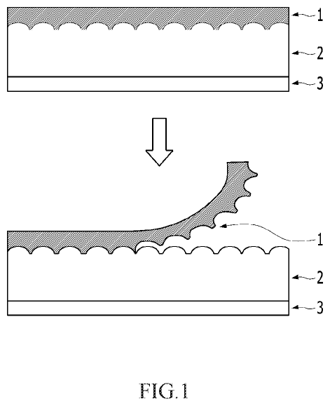

FIG. 2 is a view illustrating a black polyimide resin layer material and a producing process thereof.

FIG. 3 is a view illustrating a process of producing a coverlay film using a black polyimide film.

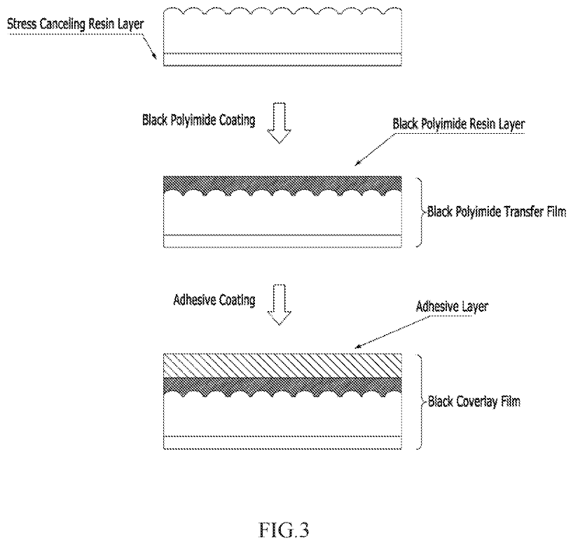

FIG. 4 is a view illustrating a process of laminating a coverlay-applied flexible circuit board using a black polyimide film.

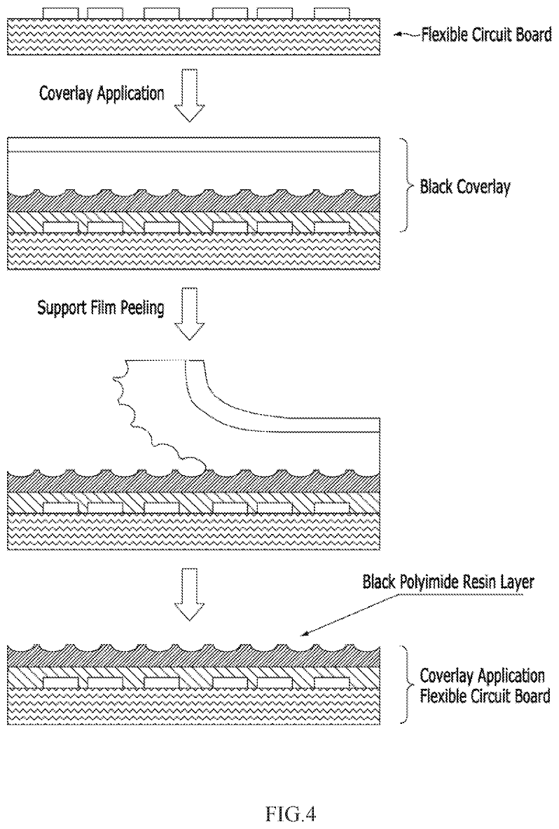

FIG. 5 illustrates a black polyimide film curl level measurement position in the present invention.

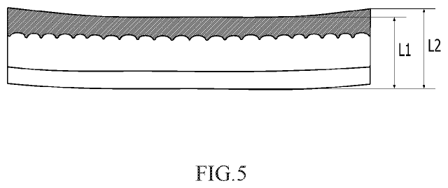

### DESCRIPTION OF EMBODIMENTS

The present invention will be described with reference to specific embodiments. These embodiments will be described in detail in such a manner that the present invention can be easily carried out by those of ordinary skill in the art. It should be understood that various embodiments of the present invention are different, but need not be mutually exclusive. For example, certain shapes, structures, and features described herein may be implemented in other embodiments without departing from the spirit and scope of the present invention in connection with one embodiment. It should also be understood that the positions or arrangements of individual components within each disclosed embodiment may be modified without departing from the spirit and scope of the present invention.

Therefore, the following detailed description is not intended as a limiting sense, and the scope of the present invention is limited only by the appended claims and the equivalents thereof, if properly described.

Hereinafter, embodiments of the present invention will be described with reference to the accompanying drawings, so that those skilled in the art can easily carry out the present invention.

The present invention relates to a low gloss black polyimide film which is produced from a solvent-soluble polyimide resin composition applied to a support film in a flexible manner. Particularly, a conventional polyimide transfer film has a problem such as curl, distortion, warpage, or the like. This is caused by a difference in physical properties between the flexible coating layer and the support film, such as shrinkage, thermal expansion, or the like due to a thermal history generated during a flexible coating process.

A stress canceling resin layer is provided on the other surface of the support film according to one embodiment of the present invention, that is, the back surface of the support film having a matt surface. Therefore, it can be used as a thin film insulation material for electromagnetic wave shielding film (EMI) or coverlay for manufacturing a flexible printed circuit board having excellent heat resistance and low gloss characteristics without causing curl, distortion, warpage, or the like even when the thermal history is applied.

According to one embodiment of the present invention, the black polyimide resin layer and the stress canceling resin layer are applied the upper surface and the lower surface of the support film in a flexible manner, respectively. Preferably, the stress canceling resin layer, the support film, and the black polyimide resin layer are laminated in this order. The soluble polyimide resin layer is used as a solvent-soluble or solvent-dissolvable layer, and the polyimide resin layer refers to a resin layer containing a black polyimide flexible coating composition or a black polyimide resin composition.

The soluble polyimide resin layer according to one embodiment of the present invention preferably includes a solvent-soluble polyimide resin composition and a carbon black, and the solvent-soluble polyimide resin layer is obtained from acid anhydride and isocyanate.

According to one embodiment of the present invention, there is provided a black polyimide film which realizes low gloss characteristics by surface transfer of a support film, without addition of a matting agent. The black polyimide film includes a black polyimide resin layer containing a solvent-soluble polyimide resin composition coated on one surface of the support film in a flexible manner. A stress canceling resin layer for stress cancellation due to thermal history during the flexible coating process is provided on the back surface of the support film having the matt surface. The thickness of the polyimide resin layer is 1 μm to 10 μm. The peel strength between the support film and the polyimide resin layer is 10 gf/25 cm to 100 gf/25 cm. The 60-degree gloss value of the inner surface of the black polyimide film layer is 0 to 60. The surface resistance is 10¹⁰Ω or more. The modulus of elasticity is 1 GPa to 5 GPa. The tensile strength is 20 Mpa to 100 Mpa. The elongation is 5% to 50%, and the glass transition temperature is 150° C. to 300° C.

In terms of the thermal stability, the glass transition temperature of the black polyimide resin layer according to one embodiment of the present invention is preferably 150° C. to 300° C.

In the present invention, a polyimide polymer may have a weight average molecular weight of 1,000 g/mol to 30,000 g/mol.

The thickness of the support film according to one embodiment of the present invention is not particularly limited as long as the flexible coating is possible. However, in terms of mechanical strength, handling performance, productivity, and the like, the thickness of the support film is appropriately in a range of 10 μm to 100 μm, and preferably 30 μm to 50 μm.

In the black polyimide film according to one embodiment of the present invention, the stress canceling resin layer may includes at least one selected from the group consisting of polyimide, polyamide imide, a polyvinyl chloride resin, polystyrene, an ABS resin, an acrylic resin, polyethylene, polypropylene, polyester, polyurethane, and cellulose acetate.

The thickness of the stress canceling resin layer according to one embodiment of the present invention is 70% to 120% of the thickness of the black polyimide resin layer, and the curl level during the flexible coating of the black polyimide resin layer is 0% to 15%. Preferably, the thickness of the stress canceling resin layer is 80% to 100% of the thickness of the black polyimide resin layer. Within this range, an optimum range capable of preventing the curl or distortion phenomenon of the black polyimide film is provided. When the thickness of the stress canceling resin layer is less than 70% of the thickness of the black polyimide resin layer, the ability to cancel the stress of the black polyimide resin layer is lowered. When the thickness of the stress canceling resin layer exceeds 120% of the thickness of the black polyimide resin layer, excessive stress causes the curl, distortion, and warpage inward from the stress canceling resin layer.

The stress canceling resin layer according to one embodiment of the present invention is not limited to a specific resin, and a resin having sufficient stress to cancel the stress generated by the polyimide resin layer may be used. Preferably, polyamide imide, polyimide, a polyvinyl chloride resin, polystyrene, an ABS resin, polyethylene, polypropylene, polyester, polyurethane, and cellulose acetate may be provided, but the present invention is not limited thereto.

The thickness of the black polyimide resin layer according to one embodiment of the present invention is 1 μm to 10 μm, and preferably 3 μm to 8 μm. When the thickness of the black polyimide resin layer is less than 1 μm, the mechanical strength of the black polyimide resin layer is lowered, and when the thickness of the black polyimide resin layer exceeds 10 μm, it becomes difficult to form a thin film.

The peel strength between the support film and the black polyimide resin layer according to one embodiment of the present invention is 4 g/cm to 40 g/cm, and preferably 20 g/cm to 40 g/cm, and the 60-degree gloss value of the inner surface of the black polyimide film layer is 0 to 60, and preferably 0 to 40. When the 60-degree gloss value of the inner surface of the black polyimide film layer exceeds 60, the covering function is deteriorated.

The surface resistance for providing the electrical insulation function according to one embodiment of the present invention is 10¹⁰Ω or more, and preferably 10¹⁶Ω or more. When the surface resistance is less than 10¹⁰Ω, the electrical insulation function is deteriorated.

According to one embodiment of the present invention, the support film is a PET film having matt characteristics, and the thickness of the support film is not particularly limited as long as the flexible coating is possible. However, in terms of mechanical strength, handling performance, productivity, and the like, the thickness of the support film is appropriately in a range of 10 μm to 100 μm, and preferably 30 μm to 50 μm.

In the black polyimide film according to one embodiment of the present invention, the black polyimide resin layer includes a solvent-soluble polyimide resin composition and a carbon black, the solvent-soluble polyimide resin composition includes an isocyanate composition and an acid anhydride, and the acid anhydride includes 80 mol % to 100 mol % of trimellitic anhydride and 0 mol % to 20 mol % of pyromellitic anhydride.

In the black polyimide film according to one embodiment of the present invention, the carbon black includes 3 wt % to 10 wt % of carbon black with respect to the polyimide resin solid.

The carbon black according to one embodiment of the present invention preferably refers to a carbon black on which surface oxidation treatment is not performed, and includes 3.0 wt % to 10.0 wt %, and preferably 5 wt % to 7 wt %, with respect to the polyimide resin solid.

A conventional method for producing a black polyimide film uses solution casting in which a polyamic acid solution is polymerized from dianhydride and diamines and the polyamic acid solution is mixed with a carbon black by using a matting agent such as silica or TiO₂, an anhydrous acid for imidation, and tertiary amines as catalysts to form a film. At this time, the polyamic acid solution is cast on an endless belt together with the mixed catalyst and dried in a predetermined temperature range. Then, the semi-dried self-supporting gel film is peeled from the endless belt, transferred to a high-temperature drying oven, and subjected to an image-forming process to provide a low gloss black polyimide film.

However, since such a composition has a large difference in specific gravity between matting particles and polyimide, sedimentation or agglomeration occurs during the process, resulting in deterioration of the electrical and mechanical properties of the black polyimide film. Particularly, in the case of a thin film of 5 μm or less, commercial production is impossible due to frequent breakage caused by a reduction in film strength according to addition of matting particles. Therefore, there is a need for developing alternative manufacturing processes.

The development of the alternative manufacturing processes according to one embodiment of the present invention may realize low gloss without addition of a matting agent. Further, since the black polyimide film according to one embodiment of the present invention includes a stress canceling resin layer, excellent flatness is provided without problems such as the curl, distortion, warpage, or the like during the flexible coating process of the soluble polyimide resin, and it is easy to realize low gloss by surface transfer of the support film. Due to the high-strength soft mechanical properties, excellent circuit traceability is provided. Therefore, it is possible to cope with ultra-thin flexible insulation material requirements for coverlay in a high-temperature pressing and laminating process for manufacturing a flexible printed wiring board.

According to one embodiment of the present invention, there is provided a polymer matrix represented by Formula 1 below, which has excellent heat resistance and solvent-soluble characteristics and is thus suitable for use as a flexible coating agent.

The acid anhydride according to one embodiment of the present invention may include trimellitic anhydride, pyromellitic dianhydride, biphenylcarboxylic dianhydride, or a derivative thereof. Specifically, as the acid anhydride, trimellitic anhydride, pyromellitic dianhydride, 3,3′,4,4′-biphenyltetracarboxylic dianhydride, pyromellitic dianhydride, 3,3′,4,4′-benzophenone tetracarboxylic anhydride, p-phenylene-bis-trimellitic dianhydride, and the like may be used. However, it is preferable to use pyromellitic dianhydride and 3,3′,4,4′-biphenyltetracarboxylic dianhydride together with trimellitic anhydride.

Among the acid anhydrides according to one embodiment of the present invention, trimellitic anhydride can improve the soluble characteristics of polyimide, and 3,3′,4,4′-biphenyltetracarboxylic dianhydride and pyromellitic dianhydride can improve heat resistance characteristics.

Diisocyanate that is usable in the present invention may include diphenylmethane-based isocyanate, toluene-based isocyanate, and a derivative thereof. Specifically, isocyanates include diphenylmethane diisocyanate, toluene diisocyanate, and the like.

In this regard, one embodiment of the present invention provides a polyimide film including the polymer matrix represented by Formula 1 below:

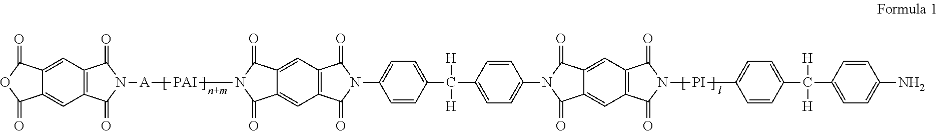

In Formula 1, A is

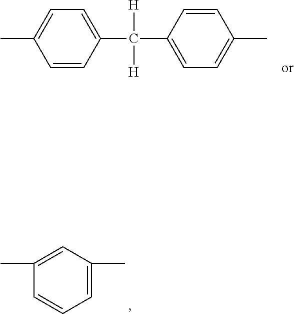

### and PAI is

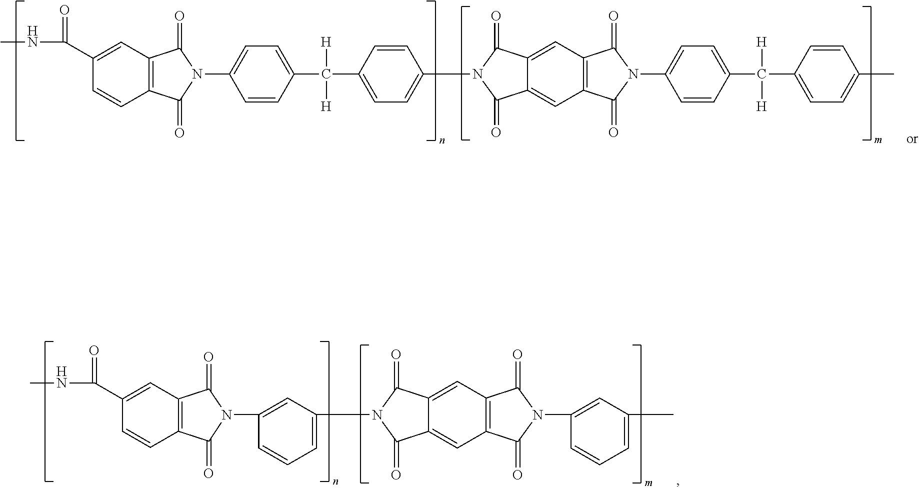

wherein n is an integer from 10 to 200, m is an integer from 5 to 50, PI is

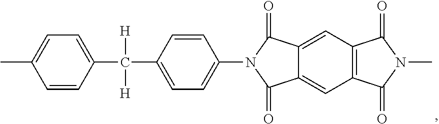

the sum of n and m is an integer from 10 to 250, and I is an integer from 5 to 200.

One embodiment of the present invention provides a coverlay film using a black polyimide film including a stress canceling resin layer, a support film, and a black polyimide resin layer coated on the support film in a flexible manner, wherein (A) low gloss is realized by surface transfer of the black polyimide resin layer coated on one surface of the support film in a flexible manner, without addition of a matting agent, (B) the stress canceling resin layer for residual stress cancellation of the black polyimide resin layer is provided on the other surface of the support film, (C) the peel strength between the support film and the black polyimide resin layer is 4 gf/cm to 40 gf/cm, (D) the 60-degree gloss value of the inner surface of the black polyimide film is 0 to 60, (E) the modulus of elasticity is 1 GPa to 5 GPa, (F) the tensile strength is 20 MPa to 100 Mpa, (G) the elongation is 5% to 50%, (H) the glass transition temperature is 150° C. to 300° C., (I) the surface resistance is 10¹⁰ Ωcm or more, and (J) the thickness is 1 μm to 10 μm.

The coverlay film according to one embodiment of the present invention refers to a film that is covered to protect circuit patterns of a flexible circuit board, but the present invention is not limited thereto. The coverlay film is laminated on the circuit patterns of the circuit board so as to protect and insulate the exposed surface thereof.

One embodiment of the present invention provides a coverlay film or an electromagnetic wave shielding film for a flexible circuit board, which uses a black polyimide film including a stress canceling resin layer, a support film, and a black polyimide resin layer coated on the support film in a flexible manner, wherein (A) low gloss is realized by surface transfer of the black polyimide resin layer coated on one surface of the support film in a flexible manner, without addition of a matting agent, (B) the stress canceling resin layer for residual stress cancellation of the black polyimide resin layer is provided on the other surface of the support film, (C) the peel strength between the support film and the black polyimide resin layer is 4 gf/cm to 40 gf/cm, (D) the 60-degree gloss value of the inner surface of the black polyimide film is 0 to 60, (E) the modulus of elasticity is 1 GPa to 5 GPa, (F) the tensile strength is 20 MPa to 100 Mpa, (G) the elongation is 5% to 50%, (H) the glass transition temperature is 150° C. to 300° C., (I) the surface resistance is 10¹⁰ Ωcm or more, and (J) the thickness is 1 μm to 10 μm.

The electromagnetic wave shielding film according to one embodiment of the present invention protects a unit circuit from electromagnetic interference (EMI) causing the malfunction of the device due to mutual interference of electromagnetic waves between adjacent circuits, overcomes electromagnetic interference, and prevents electromagnetic waves from being emitted to the outside from the electronic device.

The peel strength between the polyimide resin layer and the support film according to one embodiment of the present invention is 4 g/cm to 40 g/cm, preferably 20 g/cm to 40 g/cm, and more preferably 25 g/cm to 30 g/cm. When the peel strength is higher than 40 g/cm, the polyimide resin layer cannot be peeled off, or the film formation is not complete due to non-peeling. When the peel strength is lower than 10 g/cm, unstable adhesion force often causes a process failure due to adhesion failure of the flexible coating layer during production of the electromagnetic wave shielding film or the coverlay. Further, the 60-degree gloss value of the transfer surface of the black polyimide film is 0% to 60%, and preferably 0% to 40%. When the 60-degree gloss value of the transfer surface of the black polyimide film exceeds 60%, the covering function is deteriorated.

One embodiment of the present invention provides a method for producing a black polyimide film, including: a step (a) of coating a stress canceling resin layer on a back surface of a support film having a matt surface in a flexible manner; a step (b) of reacting at least one isocyanate compound selected from diphenylmethane diisocyanate and toluene diisocyanate with trimellitic anhydride in the presence of a solvent at 30° C. to 100° C. for 1 hour to 2 hours; a step (c) of adding pyromellitic anhydride after the step (b) and reacting at 120° C. to 140° C. for 1 hour to 4 hours; a step (d) of preparing a soluble polyimide solution by discharging carbon dioxide, which is a by-product generated after the step (c); a step (e) of adding a dispersant after the step (d) and performing a milling process; a step (f) of preparing a polyimide resin composition by adding 3 wt % to 10 wt % of a carbon black with respect to a polyimide resin solid after the step (e); and a step (g) of coating the polyimide resin layer on the support film to a thickness of 1 μm to 10 μm in a flexible manner.

The content of the carbon black added to the polyimide resin so as to realize the black color according to one embodiment of the present invention may be 3.0 wt % to 10.0 wt %, and preferably 5.0 wt % to 7.0 wt %, with respect to the polyimide resin solid by using the milling process for uniform mixing. When the content of the carbon black is less than 3.0 wt %, it is difficult to realize the black color in the thin film, and when the content of the carbon black exceeds 10.0 wt %, the insulation characteristics may be deteriorated. The carbon black may not be subjected to the surface oxidation treatment so as to improve stability during heat treatment, and it is preferable that an content of a high-temperature volatile component is small. The content of the high-temperature volatile component may be 1.5 wt % or less, and preferably 0.8 wt % to 1.5 wt %, with respect to the total content of the carbon black. Further, the volume average particle size of the carbon black may be 2 μm or less, preferably 0.5 μm to 2 μm, and more preferably 0.6 μm to 1.6 μm. When the carbon black is dispersed, the maximum particle size of the carbon black is 10 μm.

The primary particle size of the carbon black according to one embodiment of the present invention may be 70 nm or more, and preferably 70 nm to 150 nm. When the primary particle size of the carbon black is less than 70 nm, the shielding/matting characteristics are lowered, and when the primary particle size of the carbon black is greater than 150 nm, the dispersibility and the mechanical properties of the film are deteriorated. Further, when the carbon black uses carbon black particles having a low particle size dispersion degree (=volume average particle size/number average particle size) of 5 or less, and more preferably 3 or less, the particle size uniformity may increase and the carbon black particles may be uniformly dispersed in the resin, thereby achieving uniform mixing when mixed with the resin.

The particle size dispersion degree according to one embodiment of the present invention can be improved through the milling process and the application of the dispersant. The black polyimide resin is coated on the support film in a flexible manner and dried to provide a black polyimide film.

The black polyimide film formed from the black polyimide resin according to one embodiment of the present invention has excellent flexible coating property and transfer property with respect to the support film, and facilitates the thin film formation. Therefore, the black polyimide film may be used as a low gloss ultra-thin flexible material to implement an electromagnetic wave shielding film (EMI) and a coverlay insulating layer for the manufacture of a flexible circuit board. Further, due to the inclusion of the stress canceling resin layer, the curl, distortion, warpage, or the like does not occur even when thermal history is applied. Since the black polyimide film has excellent heat resistance and low gloss characteristics, productivity is improved at the same time.

### EXAMPLES

Hereinafter, the structure and operation of the present invention will be described in more detail with reference to preferred examples of the present invention. However, these example are shown by way of illustration and should not be construed as limiting the present invention in any way.

Since contents not described herein can be sufficiently technically inferred by those of ordinary skill in the art, descriptions thereof will be omitted.

Black polyimide films were produced in the following manner according to the compositions and contents of the polyimide resin layers shown in Table 1 and the thicknesses and types of the stress canceling resin layers.

### Example 1

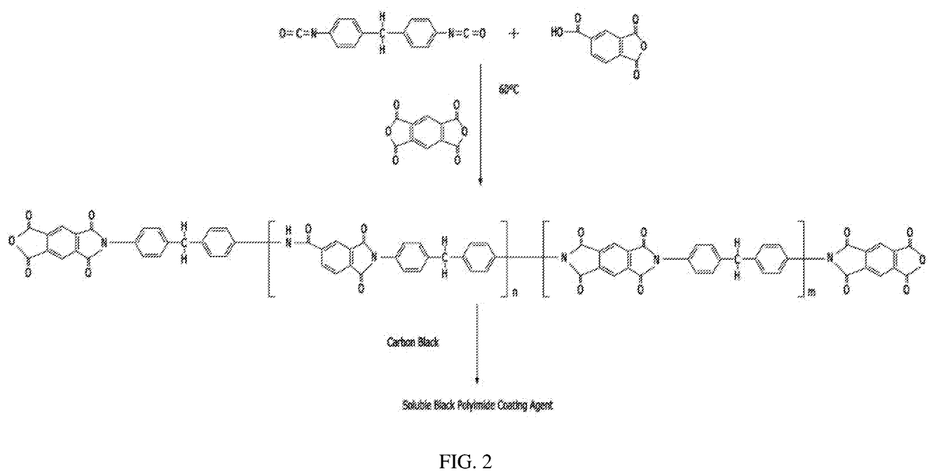

As a process of polymerizing a soluble polyimide solution, a 1-liter reactor was filled with nitrogen gas, and 51.428 g (0.268 mol) of trimellitic anhydride and 200 g of N-methyl-2-pyrrolidone were added to the reactor. Then, 79.448 g (0.3029 mol) of 4,4′-methylene diphenyl diisocyanate was dissolved in 200 g of N-methyl-2-pyrrolidone while stirring the reactor at a rotation speed of about 200 RPM, slowly added to the reactor over 1 hour, and further stirred at a speed of 200 RPM for about 30 minutes. The solution was gradually heated to 80° C. over 30 minutes and further stirred for 30 minutes, 10.303 g (0.047 mol) of pyromellitic anhydride and 125 g of N-methyl-2-pyrrolidone were added thereto in this order and stirred for 30 minutes, and then the solution was heated again to about 140° C. over about 30 minutes. Then, the solution was maintained at a temperature of 140° C. and stirred while rotating at a speed of 100 RPM for about 30 minutes. After the reaction, the solution was gradually cooled to 40° C. to produce a soluble polyimide resin having a solid content of 20% and a viscosity of 3,000 cps at room temperature. The reaction formula summarizing this is provided in FIG. 2.

The polyimide resin solution may be prepared by mixing 9 g of carbon black with the polyimide resin after milling together with a dispersant for facilitating dispersibility to produce a black polyimide resin layer. The prepared black polyimide solution had a solid content of 20% and a viscosity of 2,500 cps at room temperature. At this time, the volume average particle size of the carbon black having a primary particle size of 95 nm was 0.89 μm and the volume average particle size of the shielding agent was 0.53 μm.

The black polyimide resin was coated in a flexible manner on a back surface of a support film (polyester film) having cellulose acetate as a stress canceling layer and dried at 150° C. for 1 minute to produce a composite film having the black polyimide resin layer. At this time, the thickness of the final black polyimide resin layer was 5 μm and the thickness of the stress canceling resin layer was 6 μm.

The black polyimide film was cut to a size of 25 mm×50 mm (width×length), and the peel strength between the black polyimide resin layer and the support film was evaluated. Further, the black polyimide resin layer was peeled off, and the strength and elongation, brightness, gloss, and surface resistance were measured. Results thereof are shown in Table 2.

### Example 2

A black polyimide film was produced in the same manner as in Example 1, except that a thickness of a stress canceling resin layer in a support film was 5 μm.

### Example 3

A black polyimide film was produced in the same manner as in Example 1, except that a thickness of a stress canceling resin layer in a support film was 4 μm.

### Example 4

A black polyimide film was produced in the same manner as in Example 1, except that a trimellitic anhydride composition was 100 mol % with respect to an acid anhydride composition in a polyimide resin layer.

### Example 5

A black polyimide film was produced in the same manner as in Example 1, except that a trimellitic anhydride composition was 90 mol % with respect to an acid anhydride composition in a polyimide resin layer.

### Example 6

A black polyimide film was produced in the same manner as in Example 1, except that a trimellitic anhydride composition was 80 mol % with respect to an acid anhydride composition in a polyimide resin layer.

### Comparative Example 1

A black polyimide film was produced in the same manner as in Example 1, except that a thickness of a resin layer in a polyimide resin layer was 5 μm and the black polyimide resin layer was coated on a support film having no stress canceling resin layer in a flexible manner.

### Comparative Example 2

A black polyimide film was produced in the same manner as in Example 1, except that a thickness of a black polyimide resin layer was 5 μm, a stress canceling resin layer is cellulose acetate, and a support film having a thickness of 7 μm was used.

### Comparative Example 3

A black polyimide film was produced in the same manner as in Example 1, except that a thickness of a black polyimide resin layer was 5 μm, a stress canceling resin layer is cellulose acetate, and a support film having a thickness of 8 μm was used.

### Comparative Example 4

A black polyimide film was produced in the same manner as in Example 1, except that a trimellitic anhydride composition was 70 mol % with respect to an acid anhydride composition in a polyimide resin layer.

### Comparative Example 5

A black polyimide film was produced in the same manner as in Example 1, except that a trimellitic anhydride composition was 60 mol % with respect to a polyimide acid anhydride composition in a transfer film.

### Comparative Example 6

A black polyimide film was produced in the same manner as in Example 1, except that a trimellitic anhydride composition was 40 mol % with respect to a polyimide acid anhydride composition in a black polyimide film.

Physical properties of the black polyimide films produced in Examples 1 to 6 of the present invention and Comparative Examples 1 to 6 were measured as follows, and results thereof are shown in Table 2.

Peel Strength

Black polyimide film samples coated on the support films in a flexible manner in Examples and Comparative Examples were cut to a size of 15 mm×50 mm (width×length), and the peel strength between the black polyimide resin layer and the support film was measured. The peel strength was measured by using a universal tensile strength tester, and 180° peeling was performed under a condition of a tensile speed of 300 mm/min. Equipment name: Universal tensile strength tester

Model name: LD5

Manufacturer: LLOYD

Strength and Elongation

Black polyimide film samples coated on the support films in a flexible manner in Examples and Comparative Examples were cut to a size of 15 mm×50 mm (width×length), and the strength and elongation of the black polyimide resin layers were measured.

The strength and elongation were measured by using a universal tensile strength tester under a condition of a tensile speed of 300 mm/min.

Equipment name: Universal tensile strength tester

Model name: LD5

Manufacturer: LLOYD

Color Difference Meter

An L * (brightness) value was measured by using a color difference measurement apparatus.

Equipment name: Sepectro phtometer

Model name: CM-3600A

Manufacturer: Konica Minolata

Gloss Degree

A gloss degree was measured at 60° by using a gloss degree measurement apparatus.

Equipment name: Gloss meter

Model name: E406L

Manufacturer: Elcometer

Surface Resistance

Equipment name: Surface resistance measurement apparatus

Model name: 4339B

Manufacturer: Agilent Technology

A surface resistance was measured under 500 V by using a resistance measurement apparatus 4339B manufactured by Agilent Technology.

Curl Level

Black polyimide film samples coated on the support films in a flexible manner in Examples and Comparative Examples were cut to a size of 200 mm×200 mm (width×length), and a difference between the minimum height and the maximum height generated by the curl was measured. The curl level was calculated by the following equation.

Curl level (%)=100×(L2−L1)/L1

L1: minimum height

L2: maximum height

TABLE 1

| | | | Weight | Thickness (μm) | |
|---|---|---|---|---|---|
| | Composition | | ratio (wt %) | | Stress |
| | ratio (mol %) | | Carbon | Polyimide | canceling |
| | TMA | PDMA | black | resin layer | layer |
| Example 1 | 85 | 15 | 3.7 | 5 | 6 |
| Example 2 | 85 | 15 | 3.7 | 5 | 5 |
| Example 3 | 85 | 15 | 3.7 | 5 | 4 |
| Example 4 | 100 | 0 | 3.7 | 5 | 6 |
| Example 5 | 90 | 10 | 3.7 | 5 | 6 |
| Example 6 | 80 | 20 | 3.7 | 5 | 6 |
| Example 1 | 85 | 15 | 3.7 | 5 | 0 |
| Comparative | 85 | 15 | 3.7 | 5 | 7 |
| Example 2 | | | | | |
| Comparative | 85 | 15 | 3.7 | 5 | 8 |
| Example 3 | | | | | |
| Comparative | 70 | 30 | 3.7 | 5 | 6 |
| Example 4 | | | | | |
| Comparative | 60 | 40 | 3.7 | 5 | 6 |
| Example 5 | | | | | |
| Comparative | 40 | 60 | 3.7 | 5 | 6 |
| Example 6 | | | | | |

TABLE 2

| | | | | | | Black | | | | |
|---|---|---|---|---|---|---|---|---|---|---|
| | | | Modulus | Peel | Solvent- | resin | Gloss | Surface | | Curl |
| | Strength | Elongation | of | strength | soluble | layer | degree | resistance | | level |
| | (Mpa) | (%) | elasticity | (gf/cm) | property | (μm) | (%) | Ωcm | L* | (%) |
| Example 1 | 60 | 10 | 2.5 | 0.8 | ∘ | 5 | 21 | 10¹⁵ | 30 | 1.6 |
| Example 2 | 60 | 10 | 2.5 | 0.8 | ∘ | 5 | 22 | 10¹⁵ | 29 | 3.3 |
| Example 3 | 60 | 10 | 2.5 | 0.8 | ∘ | 5 | 22 | 10¹⁵ | 31 | 5.1 |
| Example 4 | 51 | 11 | 2.1 | 0.8 | ∘ | 5 | 23 | 10¹⁵ | 30 | 0 |
| Example 5 | 58 | 10 | 2.3 | 0.8 | ∘ | 5 | 23 | 10¹⁵ | 29 | 1.6 |
| Example 6 | 62 | 9 | 2.4 | 0.8 | ∘ | 5 | 22 | 10¹⁵ | 31 | 3.3 |
| Comparative | 61 | 8 | 2.5 | 0.7 | ∘ | 5 | 23 | 10¹⁵ | 29 | 18.2 |
| Example 1 | | | | | | | | | | |
| Comparative | 66 | 7 | 2.6 | 0.6 | ∘ | 5 | 22 | 10¹⁵ | 30 | 4.8 |
| Example 2 | | | | | | | | | | |
| Comparative | 60 | 10 | 2.5 | 0.8 | ∘ | 5 | 21 | 10¹⁵ | 30 | 15.9 |
| Example 3 | | | | | | | | | | |
| Comparative | 62 | 9 | 2.5 | 0.7 | ∘ | 5 | 22 | 10¹⁵ | 29 | 6.6 |
| Example 4 | | | | | | | | | | |
| Comparative | 61 | 8 | 2.6 | 0.7 | ∘ | 5 | 21 | 10¹⁵ | 30 | 4.9 |
| Example 5 | | | | | | | | | | |
| Comparative | — | — | — | — | x | — | — | — | — | — |
| Example 6 | | | | | | | | | | |

*In the case of Comparative Example 6, flexible coating was impossible due to the solvent-insoluble characteristics of the polymerized polyimide resin, and thus the measurement of the physical properties was impossible.

As illustrated in Tables 1 and 2, it can be confirmed that Examples 1 to 6 include 85 mol % of trimellitic anhydride (TMA), 15 mol % of pyromellitic anhydride (PDMA), and 3.7 wt % of carbon black, and the curl level is maintained at 0% to 15% when the thickness ratio of the polyimide resin layer to the stress canceling resin layer is in the range of 70% to 120%. It can be seen that there is a great difference in curl level (%) when Comparative Example 1 is compared with the case having no stress canceling resin layer, and it can be confirmed that the curl level (%) increases when the thickness ratio of the stress canceling resin layer exceeds 160%. It is also confirmed in Comparative Examples 5 to 6 that the curl level (%) increases even when the proportion of the trimellitic anhydride (TMA) is 60% or less and the proportion of pyromellitic anhydride (PDMA) is 40% or more.

1. A black polyimide film comprising:
a stress canceling resin layer;
a support film; and
a black polyimide resin layer coated on the support film in a flexible manner, wherein (A) low gloss of the back polyimide film is realized by surface transfer of the support film during flexible coating of the black polyimide resin layer, without addition of a matting agent,
(B) the stress canceling resin layer for residual stress cancellation of the black polyimide resin layer is provided on the other surface of the support film,
(C) peel strength between the support film and the black polyimide resin layer is 4 gf/cm to 40 gf/cm,
(D) a 60-degree gloss value of an inner surface of the black polyimide film is 0 to 60,
(E) modulus of elasticity is 1 GPa to 5 GPa,
(F) tensile strength is 20 MPa to 100 Mpa,
(G) elongation is 5% to 50%,
(H) a glass transition temperature is 150° C. to 300° C.,
(I) a surface resistance is 10¹⁰ Ωcm or more, and
(J) a thickness is 1 μm to 10 μm.

2. The black polyimide film according to claim 1, wherein the stress canceling resin layer comprises at least one selected from the group consisting of polyamide imide, polyimide, a polyvinyl chloride resin, polystyrene, an ABS resin, an acrylic resin, polyethylene, polypropylene, polyester, polyurethane, and cellulose acetate.

3. The black polyimide film according to claim 1, wherein the thickness of the stress canceling resin layer is 70% to 120% of the thickness of the black polyimide resin layer, and the curl level during the flexible coating of the black polyimide resin layer is 0% to 15%.

4. The black polyimide film according to claim 1, wherein the black polyimide resin layer comprises a solvent-soluble polyimide resin composition and a carbon black,
the solvent-soluble polyimide resin composition comprises an isocyanate composition and an acid anhydride, and
the acid anhydride comprises 80 mol % to 100 mol % of trimellitic anhydride and 0 mol % to 20 mol % of pyromellitic anhydride.

5. The black polyimide film according to claim 4, wherein the carbon black comprises 3 wt % to 10 wt % of carbon black with respect to a polyimide resin solid.

6. The black polyimide film according to claim 4, wherein the isocyanate comprises at least one of diphenylmethane diisocyanate and toluene.

7. A method for producing a black polyimide film, comprising:
a step (a) of coating a stress canceling resin layer on a back surface of a support film having a matt surface in a flexible manner;
a step (b) of reacting at least one isocyanate compound selected from diphenylmethane diisocyanate and toluene diisocyanate with trimellitic anhydride in the presence of a solvent at 30° C. to 100° C. for 1 hour to 2 hours;
a step (c) of adding pyromellitic anhydride after the step (b) and reacting at 120° C. to 140° C. for 1 hour to 4 hours;
a step (d) of preparing a soluble polyimide solution by discharging carbon dioxide, which is a by-product generated after the step (c);
a step (e) of adding a dispersant after the step (d) and performing a milling process;
a step (f) of preparing a polyimide resin composition by adding 3 wt % to 10 wt % of a carbon black with respect to a polyimide resin solid after the step (e); and
a step (g) of coating the polyimide resin layer on the support film to a thickness of 1 μm to 10 μm in a flexible manner.

8. A coverlay film using the black polyimide film according to claim 1.

9. A coverlay film using the black polyimide film according to claim 2.

10. A coverlay film using the black polyimide film according to claim 3.

11. A coverlay film using the black polyimide film according to claim 4.

12. A coverlay film using the black polyimide film according to claim 5.

13. A coverlay film using the black polyimide film according to claim 6.

14. An electromagnetic wave shielding film using the black polyimide film according to claim 1.

15. An electromagnetic wave shielding film using the black polyimide film according to claim 2.

16. An electromagnetic wave shielding film using the black polyimide film according to claim 3.

17. An electromagnetic wave shielding film using the black polyimide film according to claim 4.

18. An electromagnetic wave shielding film using the black polyimide film according to claim 5.

19. An electromagnetic wave shielding film using the black polyimide film according to claim 6.
